(19) United States
(12) Patent Application Publication
(10) Pub. No.: US 2026/0324204 A1
(43) Pub. Date: Oct. 15, 2026

(54) DISPLAY DEVICE, ELECTRONIC DEVICE, AND METHOD FOR MANUFACTURING DISPLAY DEVICE

(71) Applicant: Samsung Display Co., Ltd., Yongin-si (KR)

(72) Inventors: Jeongki KIM, Yongin-si (KR); Kanguk KIM, Yongin-si (KR); Jang-il KIM, Yongin-si (KR); Kyounghae MIN, Yongin-si (KR); Jiseong YANG, Yongin-si (KR); Kang Soo HAN, Yongin-si (KR); Seok-Joon HONG, Yongin-si (KR)

(73) Assignee: Samsung Display Co., Ltd., Yongin-si (KR)

(21) Appl. No.: 19/564,838

(22) Filed: Mar. 12, 2026

(30) Foreign Application Priority Data
Apr. 10, 2025 (KR) 10-2025-0046472

(51) Int. Cl. H10K 59/122; H10K 59/12

(52) U.S. Cl. CPC H10K 59/122; H10K 59/1201

(57) ABSTRACT

A display device may include: a substrate; a circuit layer on the substrate; first electrodes on and connected to the circuit layer; a bank between the first electrodes; a first functional layer on the first electrodes and at least partially in contact with the bank; a pixel defining film on the first functional layer, wherein the pixel defining film defines light-emitting regions, and the first electrodes are at least partially in the light-emitting regions; a light-emitting layer on the first functional layer; a second functional layer on the light-emitting layer; and a second electrode on the second functional layer, wherein the first functional layer has a first thickness in a first light-emitting region among the light-emitting regions and has a second thickness different from the first thickness in a second light-emitting region among the light-emitting regions.

### CROSS REFERENCE TO RELATED APPLICATION

This application claims priority to Korean Patent Application No. 10-2025-0046472, filed on Apr. 10, 2025, in the Korean Intellectual Property Office, the disclosure of which is incorporated herein by reference in its entirety.

### BACKGROUND

### 1. Field

Some embodiments of the present disclosure relate to a display device, an electronic device, and a method for manufacturing the display device, and more specifically, to a display device, an electronic device, and a method for manufacturing the display device with improved display quality and light emission efficiency.

### 2. Description of Related Art

Display technologies have become a core component in various electronic devices, such as smartphones, tablet personal computers (PCs), televisions, and wearable devices, and are evolving rapidly in response to demands for high definition, low power consumption, and lightweight construction. Particularly, displays based on light-emitting diodes, such as organic light-emitting diodes (OLEDs), utilize self-emissive characteristics to provide superior contrast ratios and color reproduction and thus occupy a prominent position in the next-generation display markets.

A tandem structure may connect multiple light-emitting units in series, enabling higher light emission efficiency and longer lifespan within the same display area. Additionally, vacuum deposition technologies may allow the formation of high-quality thin films, enabling precise control over the characteristics of the devices.

Information disclosed in this Background section has already been known to or derived by the inventors before or during the process of achieving the embodiments of the present application, or is technical information acquired in the process of achieving the embodiments. Therefore, it may contain information that does not form prior art that is already known to the public.

### SUMMARY

According to some embodiments of the present disclosure, a display device with improved display quality and light emission efficiency may be provided.

According to some embodiments of the present disclosure, an electronic device with improved display quality and light emission efficiency may be provided.

According to some embodiments of the present disclosure, a method for manufacturing a display device with improved display quality and light emission efficiency may be provided.

According to some embodiments of the present disclosure, a display device may include: a substrate; a circuit layer on the substrate; first electrodes on and connected to the circuit layer; a bank between the first electrodes; a first functional layer on the first electrodes and at least partially in contact with the bank; a pixel defining film on the first functional layer, wherein the pixel defining film defines light-emitting regions, and the first electrodes are at least partially in the light-emitting regions; a light-emitting layer on the first functional layer; a second functional layer on the light-emitting layer; and a second electrode on the second functional layer, wherein the first functional layer has a first thickness in a first light-emitting region among the light-emitting regions and has a second thickness different from the first thickness in a second light-emitting region among the light-emitting regions.

According to some embodiments of the present disclosure, at least one of the first electrodes and the bank are spaced apart from each other, and a groove is defined by and between the pixel defining film and the bank, and wherein a portion of the first functional layer is in the groove.

According to some embodiments of the present disclosure, the first functional layer is in contact with the circuit layer.

According to some embodiments of the present disclosure, the first functional layer is on an entire upper surface of at least one of the first electrodes.

According to some embodiments of the present disclosure, a non-light-emitting region is defined between the light-emitting regions, and wherein, in a direction from the light-emitting regions toward the non-light-emitting region, the first functional layer is between the pixel defining film and the bank.

According to some embodiments of the present disclosure, the first functional layer is in contact with the circuit layer, the first electrodes, the bank, the pixel defining film, and the light-emitting layer.

According to some embodiments of the present disclosure, the first functional layer comprises at least one from among a hole injection layer and a hole transport layer.

According to some embodiments of the present disclosure, the display device may further include: a light-emitting stack between the second electrode and the second functional layer; and a charge generation layer between the second functional layer and the light-emitting stack, wherein the light-emitting stack comprises: at least one stack hole functional layer; at least one stack light-emitting layer; and at least one stack electron functional layer.

According to some embodiments of the present disclosure, a first distance between a top surface of the bank and the substrate is greater than a second distance between a top surface of the pixel defining film and the substrate.

According to some embodiments of the present disclosure, the bank is on at least one of the first electrodes.

According to some embodiments of the present disclosure, the pixel defining film extends over an upper portion of the bank.

According to some embodiments of the present disclosure, a non-light-emitting region is between the light-emitting regions, and wherein the pixel defining film is on a portion of the first functional layer, the portion of the first functional layer overlapping with the non-light-emitting region in a plan view.

According to some embodiments of the present disclosure, a non-light-emitting region is between the light-emitting regions, and wherein a portion of the first functional layer overlapping with the non-light-emitting region in a plan view is exposed between the pixel defining film and the bank.

According to some embodiments of the present disclosure, the display device further includes: an encapsulation layer on the second electrode; and a color conversion layer on the encapsulation layer.

According to some embodiments of the present disclosure, the display device further includes: an encapsulation layer on the second electrode; and a color filter layer on the encapsulation layer.

According to some embodiments of the present disclosure, the bank comprises a lyophobic material.

According to some embodiments of the present disclosure, the bank comprises a colored light-shielding material, and wherein the pixel defining film comprises a transparent or translucent insulating film.

According to some embodiments of the present disclosure, a method for manufacturing a display device may include: providing a circuit layer on a substrate; providing first electrodes on the circuit layer; providing a bank between the first electrodes; providing a first functional layer on the first electrodes and at least partially in contact with the bank; providing a pixel defining film on the first functional layer; providing a light-emitting layer on the first functional layer; providing a second functional layer on the light-emitting layer; and providing a second electrode on the second functional layer, wherein the pixel defining film defines light-emitting regions, and the first electrodes are at least partially in the light-emitting regions, and wherein the first functional layer has a first thickness in a first light-emitting region among the light-emitting regions and has a second thickness different from the first thickness in a second light-emitting region among the light-emitting regions.

According to some embodiments of the present disclosure, an electronic device may include a display device including: a substrate; a circuit layer on the substrate; first electrodes on and connected to the circuit layer; a bank between the first electrodes; a first functional layer on the first electrodes and at least partially in contact with the bank; a pixel defining film on the first functional layer, wherein the pixel defining film defines light-emitting regions, and the first electrodes are at least partially in the light-emitting regions; a light-emitting layer on the first functional layer; a second functional layer on the light-emitting layer; and a second electrode on the second functional layer, wherein the first functional layer has a first thickness in a first light-emitting region among the light-emitting regions and has a second thickness different from the first thickness in a second light-emitting region among the light-emitting regions.

According to some embodiments of the present disclosure, the electronic device further includes: a processor configured to control the display device; a memory storing data for operation of the display device or the processor; and a power converter configured to generate or supply power.

### BRIEF DESCRIPTION OF DRAWINGS

These and/or other features will become apparent and more readily appreciated from the following description of the embodiments, taken in conjunction with the accompanying drawings in which:

FIG. 1 is a plan view schematically illustrating a display device according to an embodiment of the present disclosure;

FIG. 2 is a cross-sectional view schematically illustrating a display device according to an embodiment;

FIG. 3 is a cross-sectional view schematically illustrating a light-emitting diode according to an embodiment;

FIG. 4 is a cross-sectional view schematically illustrating a light-emitting stack according to an embodiment;

FIG. 5 is an enlarged view showing a region AA of FIG. 2;

FIG. 6 is a cross-sectional view illustrating a portion of a display device according to a comparative example.

FIG. 7 is a cross-sectional view illustrating a portion of a display device according to an embodiment;

FIG. 8 is a cross-sectional view illustrating a portion of a display device according to an embodiment;

FIG. 9 is a cross-sectional view illustrating a portion of a display device according to an embodiment;

FIG. 10 is a cross-sectional view illustrating a portion of a display device according to an embodiment;

FIG. 11 is a cross-sectional view illustrating a portion of a display device according to an embodiment;

FIG. 12 is a cross-sectional view illustrating a portion of a display device according to an embodiment;

FIG. 13 is a flow diagram illustrating a method for manufacturing a display device according to an embodiment of the present disclosure;

FIGS. 14A, 14B, 14C, 14D and 14E are cross-sectional views schematically illustrating parts of manufacturing steps of a display device according to an embodiment;

FIG. 15 is a block diagram of an electronic device according to an embodiment; and

FIGS. 16, 17, and 18 are schematic views of electronic devices according to various embodiments.

### DETAILED DESCRIPTION

In the following description, for the purposes of explanation, numerous specific details are set forth in order to provide a thorough understanding of various embodiments or implementations of the present disclosure. As used herein “embodiments” and “implementations” are interchangeable words that are non-limiting examples of devices and/or methods of the present disclosure. It is apparent, however, that various embodiments of the present disclosure may be practiced without these specific details or with one or more equivalent arrangements. Here, various embodiments of the present disclosure do not have to be exclusive nor limit the present disclosure. For example, specific shapes, configurations, and characteristics of an embodiment of the present disclosure may be used or implemented in another embodiment of the present disclosure.

Unless otherwise specified, the described and illustrated embodiments are to be understood as non-limiting example embodiments. Therefore, unless otherwise specified, the features, components, modules, layers, films, panels, regions, and/or aspects, etc. (hereinafter individually or collectively referred to as “elements”), of the various embodiments of the present disclosure may be otherwise combined, separated, interchanged, and/or rearranged without departing from the present disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless otherwise specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Like or identical reference numerals refer to like or identical elements. Moreover, in the accompanying drawings, the thicknesses, ratios, and dimensions of the elements may not be to exact scale and may have been exaggerated for the benefit of effective explanation of technical features associated with these elements. As such, the present disclosure shall not be restricted to the thicknesses, ratios, dimensions, etc., illustrated in the drawings. The term “and/or” shall include the combination of listed items or any of listed items that can be defined by relevant elements.

Although the terms “first,” “second,” etc., may be used herein to describe various types of elements, these elements should not be limited by these terms. These terms are used to distinguish one element from another element. Thus, a first element discussed below could be termed a second element without departing from the teachings of the present disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The term “overlap” may include “layer,” “stack,” “face” or “facing,” “extending over,” “covering” or “partly covering,” or any other suitable term as would be appreciated and understood by those of ordinary skill in the art.

The terminology used herein is for the purpose of describing non-limiting example embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of example embodiments and/or intermediate structures. As such, variations from the shapes of the illustrations as a result of, for example, manufacturing techniques and/or tolerances are to be expected. Thus, embodiments described herein should not necessarily be construed as limited to the particular illustrated shapes of regions, and are to include deviations in shapes that result from, for instance, manufacturing. In this manner, regions illustrated in the drawings may be schematic in nature and the shapes of these regions may not reflect actual shapes of regions of a device and, as such, are not limiting.

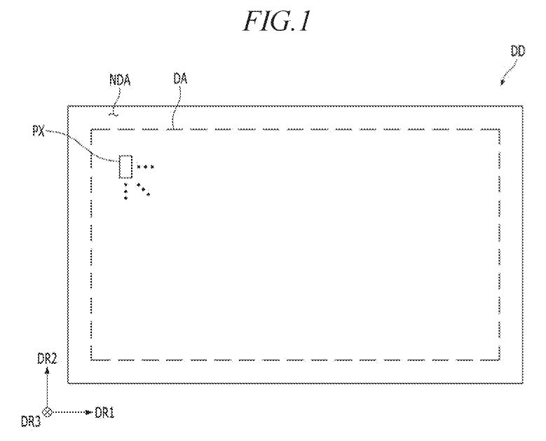

FIG. 1 is a plan view schematically illustrating a display device according to an embodiment of the present disclosure. Referring to FIG. 1, a display device DD according to an embodiment of the present disclosure may include a display area DA and a non-display area NDA disposed on at least one side of the display area DA in, for example, a first direction DR1 and/or a second direction DR2 crossing the first direction DR1. According to some embodiments, the display device DD may face towards a third direction DR3 that crosses the first direction DR1 and the second direction DR2.

The display area DA is a region where images are displayed, and a plurality of pixels PX may be arranged therein. The display area DA may have various shapes such as circular, elliptical, polygonal, or other geometrical shapes. A plurality of pixels PX including light-emitting diodes (e.g., organic light-emitting diodes) may be arranged in the display area DA. Each pixel PX may include a transistor configured to control the light-emitting diodes. A single pixel PX may include at least one transistor.

Various wirings configured to transmit electrical signals to the display area DA may be arranged in the non-display area NDA. The non-display area NDA may also include transistors, which may be part of a circuit unit configured to control the electrical signals applied to the display area DA.

Hereinafter, the display device DD according to an embodiment of the present disclosure will be described primarily in the context of an organic light-emitting display device by way of example. However, the display device of embodiments of the present disclosure is not limited thereto. In other embodiments, the display device DD may be an inorganic light-emitting display device or a quantum dot light-emitting display device. For example, the light-emitting layer of the display element included in the display device DD may include an organic material, an inorganic material, quantum dots, a combination of organic material and quantum dots, or a combination of inorganic material and quantum dots.

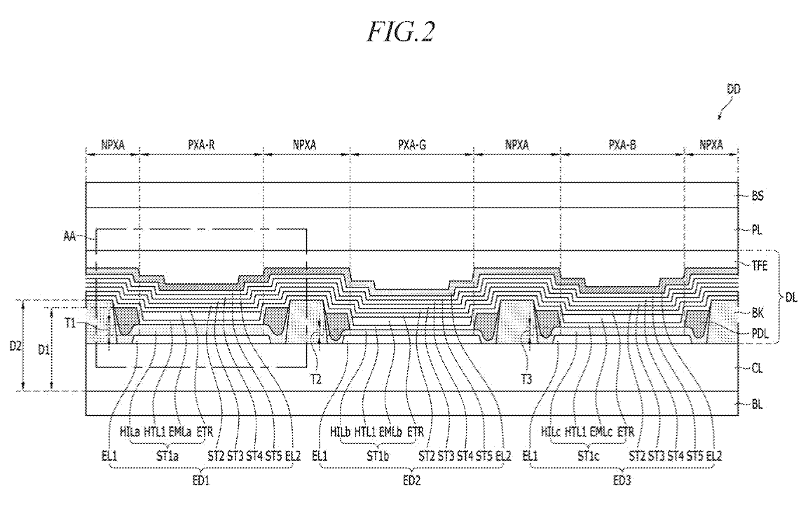

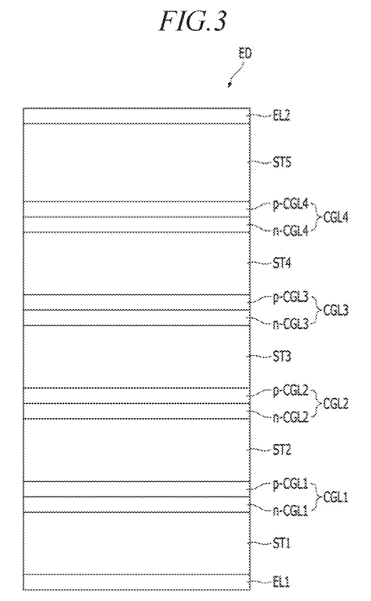

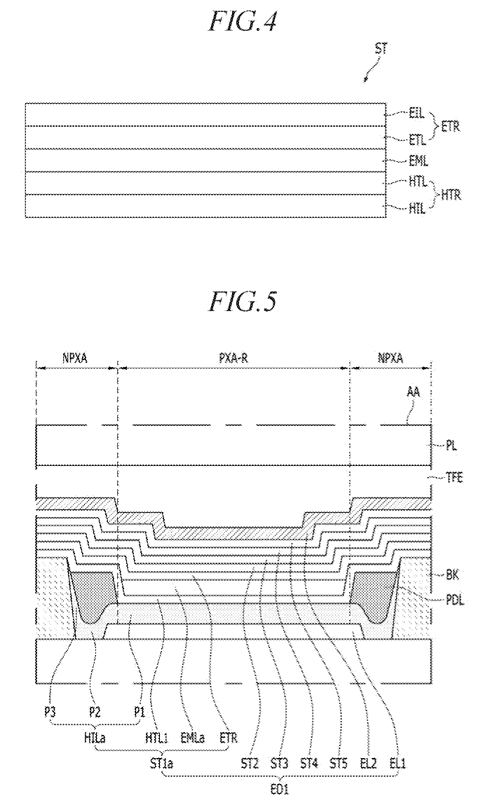

FIG. 2 is a cross-sectional view schematically illustrating a display device according to an embodiment. FIG. 3 is a cross-sectional view schematically illustrating a light-emitting diode according to an embodiment. FIG. 4 is a cross-sectional view schematically illustrating a light-emitting stack according to an embodiment.

Referring to FIG. 2, a display device DD according to an embodiment may include a substrate BL, a circuit layer CL, a display layer DL, an optical layer PL, and a base substrate BS.

The substrate BL may serve as a base surface on which the circuit layer CL is disposed. The substrate BL may be a glass substrate, a metal substrate, a plastic substrate, or the like. However, embodiments of the present disclosure are not limited thereto, and the substrate BL may also be formed of an inorganic layer, an organic layer, or a composite material layer.

In an embodiment, the circuit layer CL may be disposed on the substrate BL and may include a plurality of transistors. Each transistor may include a control electrode, an input electrode, and an output electrode. For example, the circuit layer CL may include a switching transistor and a driving transistor for driving first through third light-emitting diodes ED1, ED2, ED3 of the display layer DL.

In an embodiment, the display layer DL may be disposed on the circuit layer CL and may include light-emitting diodes (e.g., the first through third light-emitting diodes ED1, ED2, ED3), a bank BK, a pixel defining film PDL, and an encapsulation layer TFE.

According to an embodiment, the first light-emitting diode ED1, the second light-emitting diode ED2, and the third light-emitting diode ED3 may each have the structure of a light-emitting diode ED as illustrated in FIG. 3, which will be described later.

Referring to FIGS. 3 and 4, the light-emitting diode ED according to an embodiment of the present disclosure may have a tandem structure including a first electrode EL1, a second electrode EL2, and a plurality of light-emitting stacks (e.g., first through fifth light-emitting stacks ST1, ST2, ST3, ST4, ST5) disposed between the first electrode EL1 and the second electrode EL2. Each of the light-emitting stacks (e.g., the first through fifth light-emitting stacks ST1, ST2, ST3, ST4, ST5) may have the structure of a light-emitting stack ST illustrated in FIG. 4.

Although FIG. 3 illustrates an example in which the light-emitting diode ED includes five light-emitting stacks (e.g., the first through fifth light-emitting stacks ST1, ST2, ST3, ST4, ST5), embodiments of the present disclosure are not limited thereto. The number of light-emitting stacks included in the light-emitting diode ED may be adjusted to one or more.

A plurality of charge generation layers (e.g., first through fourth charge generation layers CGL1, CGL2, CGL3, CGL4) may be disposed between the light-emitting stacks (e.g., the first through fifth light-emitting stacks ST1, ST2, ST3, ST4, ST5). The light-emitting diode ED according to an embodiment may include a first charge generation layer CGL1 disposed between the first light-emitting stack ST1 and the second light-emitting stack ST2, a second charge generation layer CGL2 disposed between the second light-emitting stack ST2 and the third light-emitting stack ST3, a third charge generation layer CGL3 disposed between the third light-emitting stack ST3 and the fourth light-emitting stack ST4, and a fourth charge generation layer CGL4 disposed between the fourth light-emitting stack ST4 and the fifth light-emitting stack ST5.

The charge generation layers (e.g., the first through fourth charge generation layers CGL1, CGL2, CGL3, CGL4) may generate charges (electrons and holes) via redox reactions when a voltage is applied to the light-emitting diode ED. Each charge generation layer may supply the generated charges to the adjacent light-emitting stacks (e.g., the first through fifth light-emitting stacks ST1, ST2, ST3, ST4, ST5). The charge generation layers (e.g., the first through fourth charge generation layers CGL1, CGL2, CGL3, CGL4) can enhance current efficiency in the adjacent light-emitting stacks (e.g., the first through fifth light-emitting stacks ST1, ST2, ST3, ST4, ST5) and maintain charge balance between the adjacent light-emitting stacks (e.g., the first through fifth light-emitting stacks ST1, ST2, ST3, ST4, ST5).

Each charge generation layer (e.g., the first through fourth charge generation layers CGL1, CGL2, CGL3, CGL4) may have a layer structure formed by a junction between an n-type charge generation layer n-CGL1, n-CGL2, n-CGL3, n-CGL4 and a p-type charge generation layer p-CGL1, p-CGL2, p-CGL3, p-CGL4. The first charge generation layer CGL1 may be formed by a junction of an n-type charge generation layer n-CGL1 (a first n-type charge generation layer) and a p-type charge generation layer p-CGL1 (a first p-type charge generation layer). The second charge generation layer CGL2 may be formed by a junction of an n-type charge generation layer n-CGL2 (a second n-type charge generation layer) and a p-type charge generation layer p-CGL2 (a second p-type charge generation layer). The third charge generation layer CGL3 may be formed by a junction of an n-type charge generation layer n-CGL3 (a third n-type charge generation layer) and a p-type charge generation layer p-CGL3 (a third p-type charge generation layer). The fourth charge generation layer CGL4 may be formed by a junction of an n-type charge generation layer n-CGL4 (a fourth n-type charge generation layer) and a p-type charge generation layer p-CGL4 (a fourth p-type charge generation layer).

The n-type charge generation layers n-CGL1, n-CGL2, n-CGL3, n-CGL4 may be configured to supply electrons to the adjacent light-emitting stacks and may have n-type dopants doped in a base material thereof. The p-type charge generation layers p-CGL1, p-CGL2, p-CGL3, p-CGL4 may be configured to supply holes to the adjacent light-emitting stacks. According to some embodiments, a buffer layer may be further disposed between the n-type charge generation layers n-CGL1, n-CGL2, n-CGL3, n-CGL4 and the p-type charge generation layers p-CGL1, p-CGL2, p-CGL3, p-CGL4.

Each charge generation layer (e.g., the first through fourth charge generation layers CGL1, CGL2, CGL3, CGL4) may include an n-type arylamine-based material or a p-type metal oxide. For instance, the charge generation layers (e.g., the first through fourth charge generation layers CGL1, CGL2, CGL3, CGL4) may each include charge-generating compounds made of organic arylamine compounds, metals, metal oxides, carbides, fluorides, or mixtures thereof.

Examples of arylamine compounds may include α-NPD, 2-TNATA, TDATA, MTDATA, spiro-TAD, or spiro-NPB. Examples of metals may include cesium (Cs), molybdenum (Mo), vanadium (V), titanium (Ti), tungsten (W), barium (Ba), or lithium (Li). Examples of metal oxides, carbides, and fluorides may include Re₂O₇, MoO₃, V₂O₅, WO₃, TiO₂, Cs₂CO₃, BaF, LiF, or CsF. A light-emitting stack ST according to an embodiment may include a hole transport region HTR, a light-emitting layer EML, and an electron transport region ETR. The hole transport region HTR may be configured to transfer holes from the first electrode EL1 or the charge generation layers (e.g., the first through fourth charge generation layers CGL1, CGL2, CGL3, CGL4) to the light-emitting layer EML. The electron transport region ETR may be configured to transfer electrons from the second electrode EL2 or the charge generation layers (e.g., the first through fourth charge generation layers CGL1, CGL2, CGL3, CGL4) to the light-emitting layer EML.

In an embodiment, the light-emitting diode ED may have a structure in which the hole transport region HTR is disposed below the light-emitting layer EML and the electron transport region ETR is disposed above the light-emitting layer EML, based on the direction of light emission from the first electrode EL1 toward the second electrode EL2. However, embodiments of the present disclosure are not limited to this structure, and an inverted structure is also possible, where the electron transport region ETR is disposed below the light-emitting layer EML and the hole transport region HTR is disposed above the light-emitting layer EML.

The hole transport region HTR may include a hole injection layer HIL and a hole transport layer HTL (see hole transport layers HTL1 of FIG. 2) disposed on the hole injection layer HIL. The hole transport layer HTL may be in contact with the lower surface of the light-emitting layer EML. However, embodiments of the present disclosure are not limited thereto, and the hole transport region HTR may further include a hole-side auxiliary layer disposed on the hole transport region HTL. The auxiliary layer may include at least one from among a hole buffer layer, a light-emission auxiliary layer, and an electron blocking layer. The hole buffer layer may be configured to enhance light emission efficiency of the display device DD by compensating for resonance distance based on the wavelength of light emitted from the light-emitting layer EML. The electron blocking layer may be configured to prevent electron injection from the electron transport region ETR into the hole transport region HTR.

The electron transport region ETR may include an electron transport layer ETL and may further include an electron injection layer EIL disposed on the electron transport layer ETL. The electron transport region ETR may also further include an electron-side auxiliary layer disposed between the electron transport layer ETL and the light-emitting layer EML. The electron-side auxiliary layer may include at least one from among an electron buffer layer and a hole blocking layer. The electron buffer layer may be configured to enhance light emission efficiency of the display device DD by compensating for resonance distance based on the wavelength of light emitted from the light-emitting layer EML. The hole blocking layer may be configured to prevent hole injection from the hole transport region HTR into the electron transport region ETR.

Referring again to FIG. 2, the first electrodes EL1 of the light-emitting diodes (e.g., the first through third light-emitting diodes ED1, ED2, ED3) may be disposed on the circuit layer CL. Each of the first electrodes EL1 may be electrically connected to a plurality of transistors disposed in the circuit layer CL and may be configured to receive electrical signals for driving the light-emitting diodes (e.g., the first through third light-emitting diodes ED1, ED2, ED3).

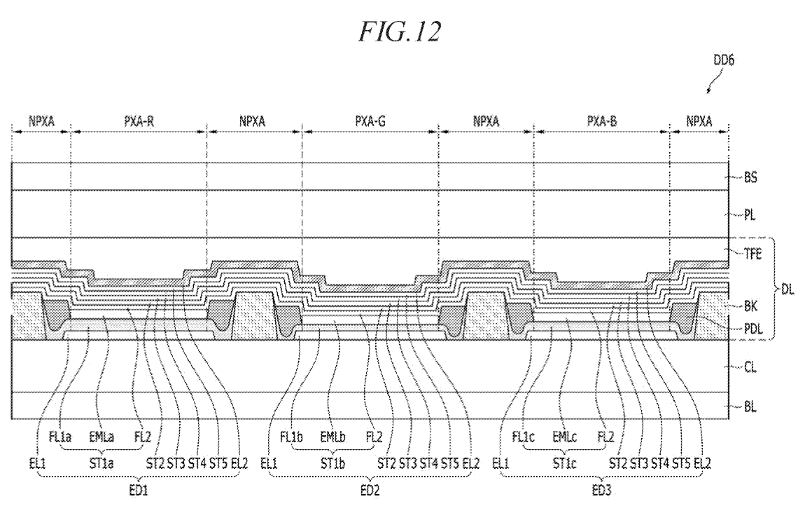

The bank BK may be disposed between the first electrodes EL1. The bank BK may define regions in which the hole injection layers HILa, HILb, HILc, or a first functional layer FL1a (see FIG. 12), are to be formed. Specifically, in an embodiment, the bank BK may include a lyophobic material, and components formed via an inkjet process may be formed in the space between portions of the bank BK.

According to embodiments, the hole injection layers HILa, HILb, HILc may together be referred to as a hole injection layer or a first functional layer.

In an embodiment, the bank BK may include a lyophobic material. In an embodiment, the bank BK may include a colored light-shielding material.

In an embodiment, the pixel defining film PDL may be disposed on at least a portion of the hole injection layers HILa, HILb, HILc, and a plurality of light-emitting regions (e.g., first through third light-emitting regions PXA-R, PXA-G, PXA-B) may be defined therein. In the present disclosure, “define” in such context may mean to establish a boundary thereof. For example, the pixel defining film PDL may define the light-emitting regions by the pixel defining film PDL establishing a boundary of the light-emitting regions. For example, the light-emitting regions may respectively correspond to holes in the pixel defining film PDL.

In an embodiment, the hole injection layers HILa, HILb, HILc may be disposed on the first electrodes EL1 and may be at least partially in contact with the bank BK.

In an embodiment, the hole injection layer HILa may have a first thickness T1 in the first light-emitting region PXA-R; the hole injection layer HILb may have a second thickness T2 in the second light-emitting region PXA-G; and the hole injection layer HILc may have a third thickness T3 in the third light-emitting region PXA-B.

In an embodiment, the first thickness T1 and the second thickness T2 may be different from each other. In an embodiment, the second thickness T2 and the third thickness T3 may be different from each other. In an embodiment, the first thickness T1, the second thickness T2, and the third thickness T3 may all be different from each other.

According to an embodiment, in a direction from the light-emitting regions (e.g., the first through third light-emitting regions PXA-R, PXA-G, PXA-B) toward the non-light-emitting region NPXA, the hole injection layers HILa, HILb, HILc may be disposed between the pixel defining film PDL and the bank BK. As will be described later in the method of manufacturing the display device DD, this structure can be formed by forming and then disposing the pixel defining film PDL on a portion of the hole injection layers HILa, HILb, HILc and on the bank BK.

In an embodiment, each of the hole injection layers HILa, HILb, HILc may be in contact (e.g., direct contact) with the circuit layer CL, the first electrode EL1, the bank BK, the pixel defining film PDL, and a corresponding light-emitting layer EMLa, EMLb, EMLc.

According to an embodiment, a second distance D2 between a top surface of the bank BK and a top surface of the substrate BL may be greater than a first distance D1 between a top surface of the pixel defining film PDL and the top surface of the substrate BL. For example, the height of the top surface of the pixel defining film PDL may be lower than the height of the top surface of the bank BK. In such a case, the pixel defining film PDL and the bank BK may form a step-like structure, allowing components disposed thereon to be formed in a stable manner. Additionally, due to the thickness of the pixel defining film PDL, the first electrode EL1 and the second electrode EL2 may be spaced apart such that the light-emitting diodes (e.g., the first through third light-emitting diodes ED1, ED2, ED3) operate in the light-emitting regions (e.g., the first through third light-emitting regions PXA-R, PXA-G, PXA-B) but do not operate in the non-light-emitting region NPXA.

The encapsulation layer TFE may be disposed on the second electrode EL2. The encapsulation layer TFE may be configured to prevent or minimize the formation of a path through which moisture or oxygen from the outside could infiltrate into the light-emitting diodes (e.g., the first through third light-emitting diodes ED1, ED2, ED3).

The encapsulation layer TFE may include at least one inorganic encapsulation layer and at least one organic encapsulation layer.

The inorganic encapsulation layer may include at least one inorganic material. The inorganic encapsulation layer may include ceramic, metal oxide, metal nitride, metal carbide, metal oxynitride, indium oxide (In₂O₃), tin oxide (SnO₂), indium tin oxide (ITO), silicon oxide, silicon nitride, and/or silicon oxynitride, among others. The inorganic encapsulation layer may be provided as a single layer or a multilayer structure.

The organic encapsulation layer may include one or more materials selected from the group consisting of acrylic, metacrylic, polyester, polyethylene, polypropylene, polyethylene terephthalate (PET), polyethylene naphthalate, polycarbonate, polyimide, polyethylene sulfonate, polyoxymethylene, polyarylate, and hexamethyldisiloxane.

The display device DD may include the optical layer PL disposed on the display layer DL. The optical layer PL may be configured to control reflected light caused by external light. The optical layer PL may include, for example, a polarizing layer or a color filter layer. Meanwhile, according to some embodiments, the optical layer PL may be omitted from the display device DD.

The base substrate BS may be disposed on the optical layer PL. The base substrate BS may serve as a base surface on which the optical layer PL is disposed. The base substrate BS may be a glass substrate, a metal substrate, or a plastic substrate. However, embodiments of the present disclosure are not limited thereto, and the base substrate BS may be formed of an inorganic layer, an organic layer, or a composite material layer. Additionally, according to some embodiments, the base substrate BS may be omitted from the display device DD.

In the display device DD according to an embodiment of the present disclosure, the light-emitting diodes (e.g., the first through third light-emitting diodes ED1, ED2, ED3) may each have a different thickness to enhance the light emission efficiency in a vacuum for each pixel. In an embodiment, the thickness of each light-emitting diode (e.g., the first through third light-emitting diodes ED1, ED2, ED3) may be adjusted by adjusting the thickness of the hole injection layer included in each light-emitting diode (e.g., the first through third light-emitting diodes ED1, ED2, ED3). Accordingly, the display device DD may have a resonance distance optimized for each pixel and exhibit improved light-emission efficiency.

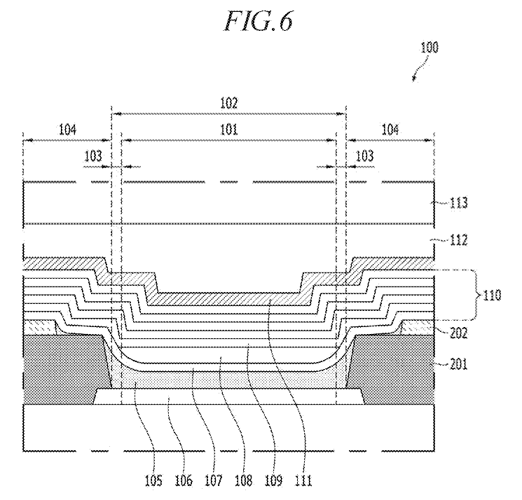

FIG. 5 is an enlarged view showing a region AA of FIG. 2. FIG. 6 is a cross-sectional view illustrating a portion of a display device according to a comparative example.

Referring to FIG. 5, in an embodiment of the present disclosure, the pixel defining film PDL may be disposed on a portion of the hole injection layer HILa, and the thickness of an entire portion of the hole injection layer HILa in the first light-emitting region PXA-R may be uniform. Accordingly, in the first light-emitting region PXA-R defined by the pixel defining film PDL, the first light-emitting diode ED1 may exhibit uniform display quality. According to some embodiments, the pixel defining film PDL may also be disposed on portions of other hole injection layers (e.g., hole injection layer HILb and HILc), and entire portions of the other hole injection layers (e.g., hole injection layer HILb and HILc) in the corresponding light-emitting region (e.g., the second light-emitting region PXA-G and the third light-emitting region PXA-B) may also have a uniform thickness.

In an embodiment of the present disclosure, the hole injection layer HILa (and/or the hole injection layer HILb and HILc) may be formed by an inkjet process. In such a case, the bank BK may include a lyophobic component, such that the hole injection layer HILa (and/or the hole injection layer HILb and HILc) is formed within an interior space enclosed by the bank BK.

Referring to FIG. 6, a display device 100 according to a comparative example includes a hole injection layer 105 disposed on portions of a first electrode 106 and a pixel defining film 201. A hole transport layer 107 is disposed on the hole injection layer 105, and a light-emitting layer 108 is disposed on the hole transport layer 107. A plurality of light-emitting stacks 110 are disposed on the light-emitting layer 108, and a second electrode 111 is disposed on the light-emitting stacks 110. An encapsulation layer 112 is provided on the second electrode 111, and an optical layer 113 is provided on the encapsulation layer 112. In the display device 100 of the comparative example, the hole injection layer 105 is formed inside the bank 202 via an inkjet process.

In a light-emitting region 101 defined by the pixel defining film 201, the thickness of the hole injection layer 105 in the comparative display device 100 is not uniform overall. As a result, the display includes a first region 102 that emits light in a normal wavelength band and a second region 103 that emits light in an abnormal wavelength band, wherein the first region 102 and the second region 103 are surrounded by a non-light emitting region 104. A display device including a structure in which the hole injection layer 105, such as in the second region 103, has a non-uniform thickness may exhibit visible blemishes on the screen and degraded display quality. Moreover, the area of the first region 102, which emits light in the normal wavelength band, is limited by the second region 103, thereby restricting the available area for emission of light in the normal wavelength band.

In contrast, in an embodiment of the present disclosure, the display device DD has a hole injection layer HILa (and/or the hole injection layer HILb and HILc) with uniform thickness in the light-emitting region PXA-R (and/or the second light-emitting region PXA-G and the third light-emitting region PXA-B) defined by the pixel defining film PDL. As a result, the display device DD can provide improved display quality, secure a wider light-emitting area, and achieve enhanced light-emission efficiency.

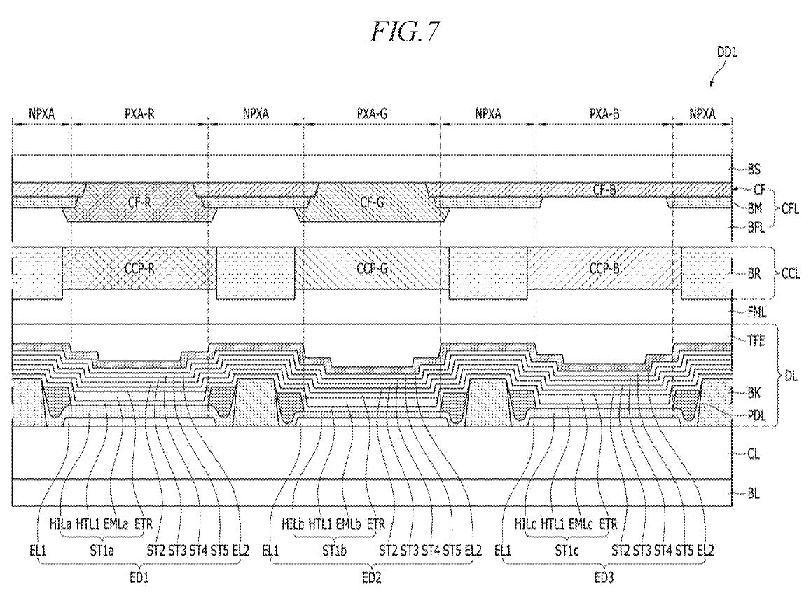

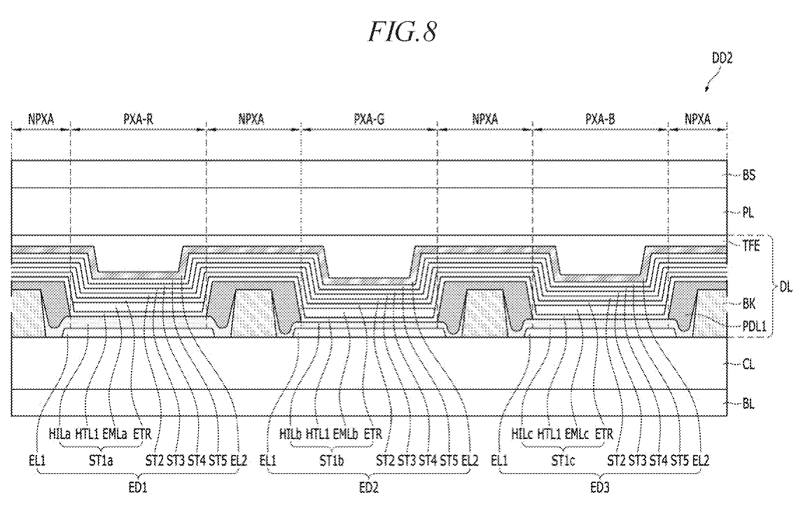

FIG. 7 is a cross-sectional view illustrating a portion of a display device according to an embodiment. Referring to FIG. 7, a display device DD1 may further include a filling layer FML and a color control layer CCL. In an embodiment, the display device DD1 may further include a color filter layer CFL.

The filling layer FML may fill the space between the display layer DL and the color control layer CCL. The filling layer FML may be disposed on the encapsulation layer TFE and may be in contact (e.g., direct contact) with the encapsulation layer TFE.

The filling layer FML may function as a buffer between the display layer DL and the color control layer CCL. In an embodiment, the filling layer FML may have shock-absorbing properties and may be configured to enhance the mechanical strength of the display device DD. The filling layer FML may be formed from a filling resin containing a polymer resin. For example, the filling layer FML may be formed from a resin that includes an acrylic resin or an epoxy resin.

The color control layer CCL may include a plurality of barriers BR spaced apart from one another, and color control portions (e.g., a first color control portion CCP-R, a second color control portion CCP-G, and a third color control portion CCP-B) disposed between the barriers BR. Each barrier BR may be formed from a polymer resin and a lyophobic additive. The barrier BR may also include a light-absorbing material, a pigment, or a dye. For example, the barrier BR may include a black pigment or a black dye to implement a black barrier. When forming a black barrier, carbon black may be used as the black pigment or dye, although embodiments of the present disclosure are not limited thereto.

The color control layer CCL may include a first color control portion CCP-R configured to transmit first color light, a second color control portion CCP-G including quantum dots for converting first color light into second color light, and a third color control portion CCP-B including quantum dots for converting first color light into third color light. The second color light may be in a longer wavelength range than a wavelength range of the third color light, and the first color light may be in a longer wavelength range than wavelength ranges of both the second and third color lights. For example, the first color light may be red light, the second color light may be green light, and the third color light may be blue light.

The color filter layer CFL may include a light-shielding portion BM and a color filter portion CF. The color filter portion CF may include a plurality of filters (e.g., first through third filters CF-R, CF-G, CF-B). That is, the color filter layer CFL may include a first filter CF-R that is configured to transmit first color light, a second filter CF-G that is configured to transmit second color light, and a third filter CF-B that is configured to transmit third color light. For example, the first filter CF-R may be a red filter, the second filter CF-G may be a green filter, and the third filter CF-B may be a blue filter.

Each of the filters (e.g., the first through third filters CF-R, CF-G, CF-B) may include a photosensitive polymer resin and a pigment or dye. The first filter CF-R may include a red pigment or dye, the second filter CF-G may include a green pigment or dye, and the third filter CF-B may include a blue pigment or dye. However, embodiments of the present disclosure are not limited thereto, and the third filter CF-B may exclude a pigment or dye. The third filter CF-B may include a photosensitive polymer resin and may be transparent. The third filter CF-B may be formed of a transparent photosensitive resin.

The light-shielding portion BM may be a black matrix. The light-shielding portion BM may include an organic or inorganic light-blocking material containing a black pigment or dye. The light-shielding portion BM may be configured to prevent light leakage and may define boundaries between adjacent filters (e.g., the first through third filters CF-R, CF-G, CF-B).

The color filter layer CFL may further include a buffer layer BFL. The buffer layer BFL may serve as a protective layer for the filters (e.g., the first through third filters CF-R, CF-G, CF-B). The buffer layer BFL may be an inorganic layer including at least one inorganic material such as silicon nitride, silicon oxide, and silicon oxynitride. The buffer layer BFL may be formed as a single layer or a multi-layer structure.

In the display device DD1 according to an embodiment shown in FIG. 7, the first filter CF-R of the color filter layer CFL is depicted as overlapping with the second filter CF-G and the third filter CF-B, but embodiments of the present disclosure are not limited thereto. For example, the first through third filters CF-R, CF-G, CF-B may be separated by the light-shielding portion BM and may be non-overlapping in a plan view. In an embodiment, the first through third filters CF-R, CF-G, CF-B may be disposed to correspond to the first light-emitting region PXA-R, the second light-emitting region PXA-G, and the third light-emitting region PXA-B, respectively.

FIG. 8 is a cross-sectional view illustrating a portion of a display device according to an embodiment. Referring to FIG. 8, in a display device DD2 according to an embodiment, a pixel defining film PDL1 may extend over a bank BK and may cover the bank BK. In the display device DD2 having such a structure, components disposed on the bank BK are positioned on the pixel defining film PDL1 without being in direct contact with the bank BK such that the components disposed on the bank BK can be formed with enhanced structural stability.

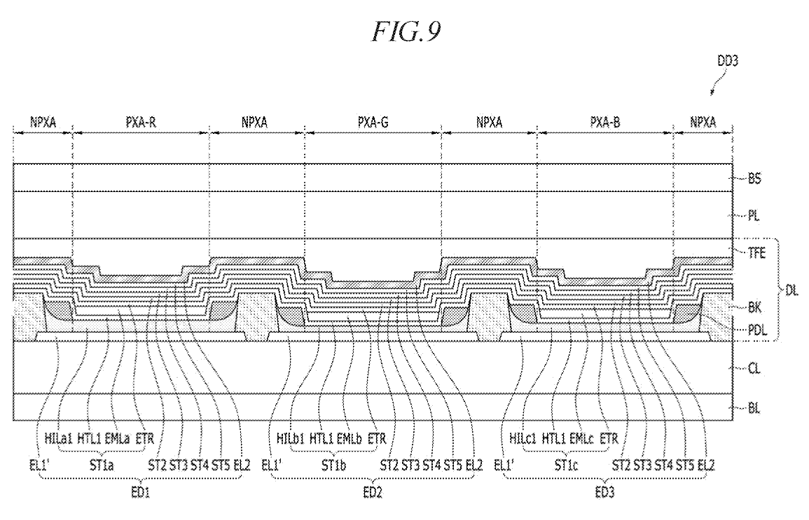

FIG. 9 is a cross-sectional view illustrating a portion of a display device according to an embodiment. Referring to FIG. 9, in a display device DD3 according to an embodiment, a first electrode EL1′ extends in a direction parallel to an extending direction of a substrate BL, and a bank BK may be disposed on at least a portion of the first electrode EL1′. In other words, the bank BK in this embodiment may cover one side of the first electrode EL1′. Hole injection layers HILa1, HILb1, HILc1 may be disposed on at least a portion of the bank BK and the first electrode EL1′, and a pixel defining film PDL may be disposed on a portion of the hole injection layers HILa1, HILb1, HILc1. In the display device DD3 having such a structure, the first electrode EL1′ can be formed flatly in the light-emitting regions (e.g., the first through third light-emitting regions PXA-R, PXA-G, PXA-B), and the hole injection layers HILa1, HILb1, HILc1 disposed on the first electrode EL1′ can be formed with enhanced stability. Furthermore, the thickness control of the hole injection layers HILa1, HILb1, HILc1 for adjusting the optical cavity length of each light-emitting diode (e.g., the first through third light-emitting diodes ED1, ED2, ED3) can be facilitated.

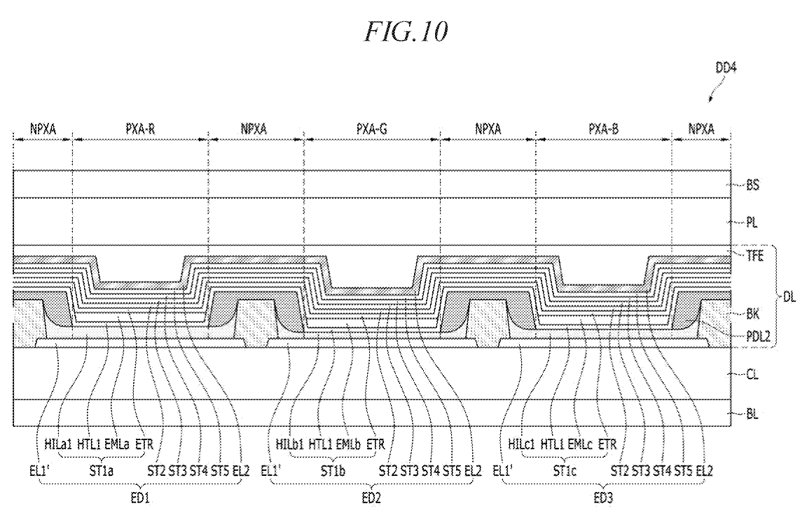

FIG. 10 is a cross-sectional view illustrating a portion of a display device according to an embodiment. Referring to FIG. 10, in a display device DD4 according to an embodiment, a first electrode EL1′ may extend in a direction parallel to an extending direction of a substrate BL, and a bank BK may be disposed on at least a portion of the first electrode EL1′. Additionally, a pixel defining film PDL2 in this embodiment may extend over the bank BK and may cover the bank BK. In the display device DD4 having such a structure, components disposed on the bank BK may be formed on the pixel defining film PDL2 without being in direct contact with the bank BK. As a result, the components disposed above the bank BK can be formed with improved structural stability. Furthermore, in the light-emitting regions (e.g., the first through third light-emitting regions PXA-R, PXA-G, PXA-B), the first electrode EL1′ can be formed flatly, and the hole injection layers HILa1, HILb1, HILc1 disposed on the first electrode EL1′ can also be formed more stably. The thicknesses of the hole injection layers HILa1, HILb1, HILc1 can be easily controlled to adjust the optical cavity lengths of the respective light-emitting diodes (e.g., the first through third light-emitting diodes ED1, ED2, ED3).

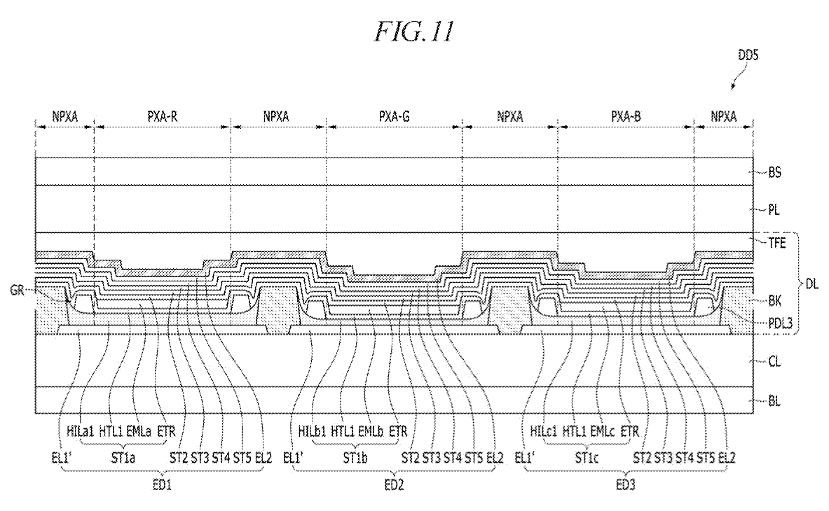

FIG. 11 is a cross-sectional view illustrating a portion of a display device according to an embodiment. Referring to FIG. 11, in a display device DD5 according to an embodiment, a pixel defining film PDL3 may be disposed on a portion of hole injection layers HILa1, HILb1, HILc1 and may form a groove GR with a portion of the hole injection layers HILa1, HILb1, HILc1 that is in contact with a bank BK. The presence of such a groove GR under the stacked structures may hinder current flow in the non-light-emitting region NPXA, thereby reducing lateral leakage. As a result, the light-emission efficiency of the light-emitting diodes (e.g., the first through third light-emitting diodes ED1, ED2, ED3) can be improved.

FIG. 12 is a cross-sectional view illustrating a portion of a display device according to an embodiment. Referring to FIG. 12, in a display device DD6 according to an embodiment, a first functional layer FL1a may be disposed on a first electrode EL1 and may be at least partially in contact with a bank BK. A pixel defining film PDL may be disposed on at least a portion of the first functional layer FL1a.

According to an embodiment, first functional layers FL1a, FL1b, FL1c may be hole functional layers including a hole injection layer and a hole transport layer. According to embodiments, the hole transport region HTR (or the hole transport layer HTL and/or the hole injection layer HIL thereof) (see FIG. 4) may be an example of the first functional layers FL1a, FL1b, FL1c. However, embodiments of the present disclosure are not limited thereto, and when the display device DD employs an inverted device structure, the first functional layers FL1a, FL1b, FL1c may be electron functional layers, including an electron injection layer and/or an electron transport layer. Similarly, the descriptions above with reference to FIGS. 2 to 11 concerning the hole injection layers are not limited to hole injection layers. For example, in inverted structures, electron injection layers may be used in the corresponding positions of the hole injection layers described above with reference to FIGS. 2 to 11. According to embodiments, the first functional layers FL1a, FL1b, FL1c may be together referred to as a first functional layer.

According to an embodiment, the bank BK may define regions where the first functional layers FL1a, FL1b, FL1c are formed.

According to an embodiment, the first functional layers FL1a, FL1b, FL1c may be disposed on the first electrodes EL1 and be in partial contact with the bank BK.

According to an embodiment, the first functional layers FL1a, FL1b, FL1c may have different thicknesses in the first to third light-emitting regions PXA-R, PXA-G, PXA-B, respectively.

According to an embodiment, in a direction (e.g., horizontal direction) from the light-emitting regions (e.g., the first through third light-emitting regions PXA-R, PXA-G, PXA-B) toward the non-emitting region NPXA, the first functional layers FL1a, FL1b, FL1c may be disposed between the pixel defining film PDL and the bank BK. Such a structure may be formed by forming the pixel defining film PDL after forming the first functional layers FL1a, FL1b, FL1c and then disposing the pixel defining film PDL on a portion of the hole injection layers HILa, HILb, HILc and the bank BK.

According to an embodiment, the first functional layers FL1a, FL1b, FL1c may each contact the circuit layer CL, the first electrode EL1, the bank BK, the pixel defining film PDL, and a corresponding light-emitting layer EMLa, EMLb, EMLc.

According to an embodiment, the pixel defining film PDL may be disposed on at least a portion of the first functional layers FL1a, FL1b, FL1c and may have a plurality of light-emitting regions (e.g., the first through third light-emitting regions PXA-R, PXA-G, PXA-B) defined therein.

As described above, to enhance the optical emission efficiency in a vacuum for each pixel, the display device DD6 may have the light-emitting diodes (e.g., the first through third light-emitting diodes ED1, ED2, ED3) each with a different thickness. In an embodiment, the thickness of each light-emitting diode (e.g., the first through third light-emitting diodes ED1, ED2, ED3) may be adjusted by adjusting the thickness of the corresponding first functional layer FL1a, FL1b, FL1c. Thus, the display device DD6 according to an embodiment may have a resonance distance optimized for each pixel and exhibit improved light-emission efficiency.

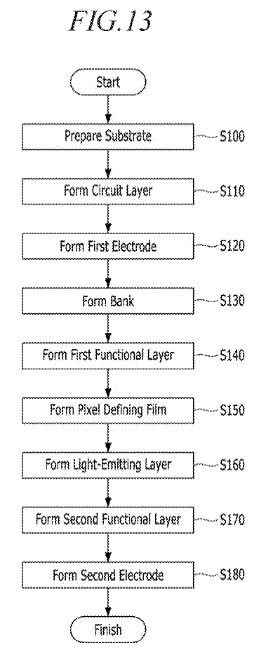

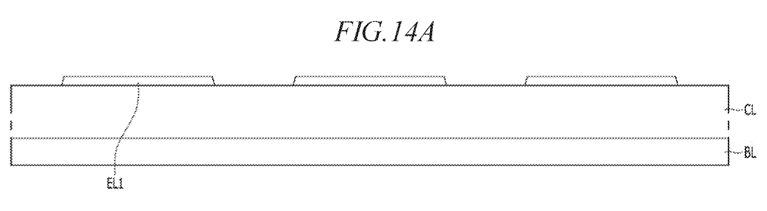

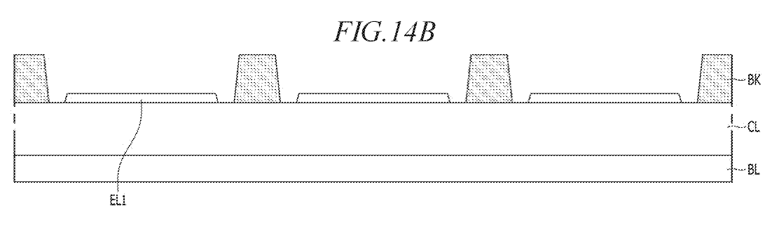

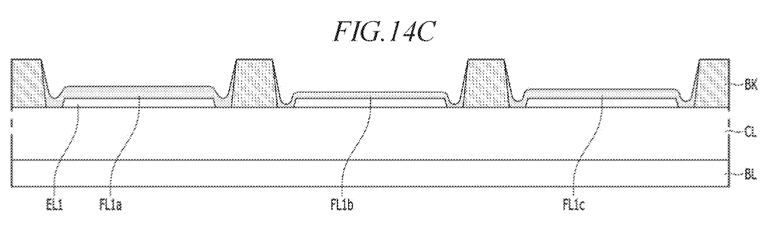

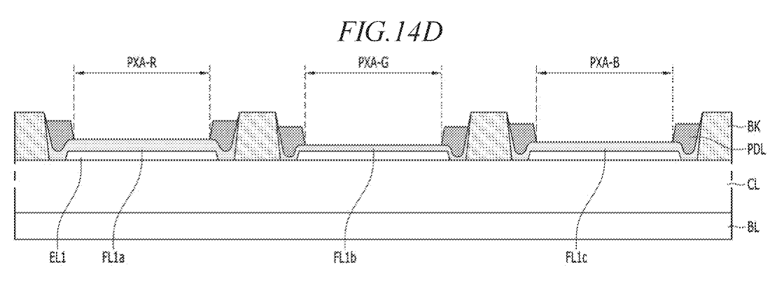

FIG. 13 is a flow diagram illustrating a method for manufacturing a display device according to an embodiment of the present disclosure. FIGS. 14A through 14E are cross-sectional views schematically illustrating parts of manufacturing steps of a display device according to an embodiment.

Referring to FIG. 13, a method for manufacturing a display device according to an embodiment may include: preparing a substrate (operation S100), forming a circuit layer (operation S110), forming a first electrode (operation S120), forming a bank (operation S130), forming a first functional layer (operation S140), forming a pixel defining film (operation S150), forming a light-emitting layer (operation S160), forming a second functional layer (operation S170), and forming a second electrode (operation S180).

Referring to FIGS. 13 and 14A, in the method for manufacturing a display device according to an embodiment, a substrate BL may be prepared in operation S100, a circuit layer CL may be formed on the substrate BL in operation S110, and a plurality of first electrodes EL1 may be formed on the circuit layer CL in operation S120.

Referring to FIGS. 13 and 14B, in operation S130, a bank BK may be formed between the first electrodes EL1. In FIG. 14B, the bank BK is illustrated as being disposed between the first electrodes EL1 without contacting the first electrodes EL1. However, embodiments of the present disclosure are not limited thereto. In another embodiment, the bank BK may be disposed on at least a portion of the first electrodes EL1 and may cover one side of the first electrodes EL1.

Referring to FIGS. 13 and 14C, in operation S140, first functional layers FL1a, FL1b, FL1c may be formed on at least a portion of the bank BK and on the first electrodes EL1. Each of the first functional layers FL1a, FL1b, FL1c may be a hole injection layer or a hole functional layer including a hole injection layer and a hole transport layer. However, embodiments of the present disclosure are not limited thereto. In an embodiment where the display device DD has an inverted device structure, each of the first functional layers FL1a, FL1b, FL1c may be an electron injection layer or an electron functional layer including an electron injection layer and an electron transport layer.

In an embodiment, the first functional layers FL1a, FL1b, FL1c may be formed by an inkjet process and may have different thicknesses in each of the light-emitting regions defined by a pixel defining film PDL (see FIG. 14D), which will be described later.

Referring to FIGS. 13 and 14D, in operation S150, a pixel defining film PDL may be formed on at least a portion of the first functional layers FL1a, FL1b, FL1c. A plurality of light-emitting regions (e.g., the first through third light-emitting regions PXA-R, PXA-G, PXA-B) may be defined by the pixel defining film PDL.

Referring to FIGS. 13 and 14E, in operation S160, light-emitting layers EMLa, EMLb, EMLc may be formed on a portion of the pixel defining film PDL and the first functional layers FL1a, FL1b, FL1c. In operation S170, second functional layers FL2a, FL2b, FL2c may be formed on the first functional layers FL1a, FL1b, FL1c, the pixel defining film PDL, and the bank BK. According to embodiments, the electron transport region ETR (or the electron transport layer ETL and/or the electron injection layer EIL thereof) (see FIG. 4) may be an example of the second functional layers FL2a, FL2b, FL2c. According to embodiments, the light-emitting layers EMLa, EMLb, EMLc may be together referred to as a light-emitting layer, and the second functional layers FL2a, FL2b, FL2c may be together referred to as a second functional layer.

In an embodiment, the first functional layers FL1a, FL1b, FL1c may be provided as hole injection layers. In such a case, the method may further include, between operations S150 and S160, forming first auxiliary layers SB1a, SB1b, SB1c on the pixel defining film PDL and the first functional layers FL1a, FL1b, FL1c. The first auxiliary layers SB1a, SB1b, SB1c may include hole transport layers. According to embodiments, the first auxiliary layers SB1a, SB1b, SB1c may be together referred to as a first auxiliary layer.

In an embodiment, the first functional layers FL1a, FL1b, FL1c may be provided as electron injection layers, in which case, the method may further include, between operations S150 and S160, forming first auxiliary layers SB1a, SB1b, SB1c on the pixel defining film PDL and the first functional layers FL1a, FL1b, FL1c. The first auxiliary layers SB1a, SB1b, SB1c may include hole transport layers.

In an embodiment, subsequently, second through fifth light-emitting stacks ST2, ST3, ST4, ST5 may be formed on the first light-emitting stacks ST1a, ST1b, ST1c, thereby forming a tandem structure. In operation S180, a second electrode EL2 may be formed on the fifth light-emitting stack ST5. Thereafter, an encapsulation layer TFE, an optical layer PL, and a base substrate BS may be formed on the second electrode EL2.

In the method for manufacturing a display device according to an embodiment of the present disclosure, after forming the first electrode and the bank, the first functional layer may be formed on the first electrode and the bank via an inkjet process. The first functional layer may have different thicknesses in each light-emitting region, enabling the vacuum distance of each light-emitting device to be adjusted. Furthermore, the first functional layer may have a uniform thickness in each light-emitting region, allowing the light-emitting device to exhibit uniform display quality in the light-emitting region. Accordingly, the display device may have improved display quality and a wider light-emitting area, thereby achieving enhanced light-emission efficiency.

The display device according to an embodiment of the present disclosure may be applied to various electronic devices. The electronic device according to an embodiment may include the above-described display devices (e.g., the display devices DD, and the display devices DD1 through DD6) and may further include other modules or devices providing additional functions besides the display device.

In an embodiment, the electronic device may include a display device and may further include a processor configured to control the display device, a memory in which data for operating the display device or the processor is stored, and a power conversion module configured to generate or supply power.

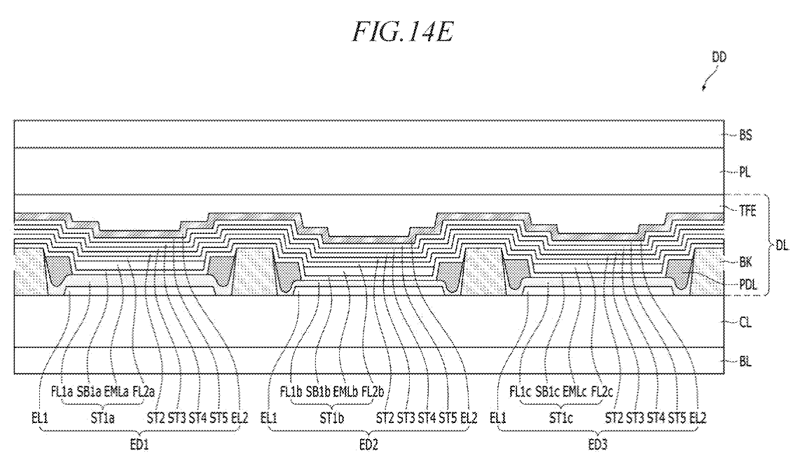

FIG. 15 is a block diagram of an electronic device according to an embodiment of the present disclosure. Referring to FIG. 15, an electronic device 10 according to an embodiment may include a display module 11, a processor 12, a memory 13, and a power module 14. The electronic device 10 may further include an input module 15, a non-image output module 16, and/or a communication module 17.

The electronic device 10 may be configured to output various information in the form of images through the display module 11. When the processor 12 executes an application stored in the memory 13, image information provided by the application may be presented to the user via the display module 11. The power module 14 may include a power supply module (e.g., a power supply), such as a power adapter or battery device, and a power conversion module (e.g., a power converter) configured to convert power supplied by the power supply module into power required for the operation of the electronic device 10. The input module 15 may be configured to provide input information to the processor 12 and/or the display module 11. The non-image output module 16 may be configured to receive and provide to the user non-image information, such as audio, haptic feedback, or light emission, transmitted from the processor 12. The communication module 17 may be responsible for transmitting and receiving information between the electronic device 10 and an external device, and may include a receiver and a transmitter.

At least one of the components of the electronic device 10 described above may be included in the display device according to the embodiments described above. Additionally, some of the individual modules that are functionally included in a single module may be included within the display device, while others may be provided separately from the display device. For example, the display device may include the display module 11, while the processor 12, memory 13, and power module 14 may be provided as components of another device within the electronic device 10, rather than within the display device.

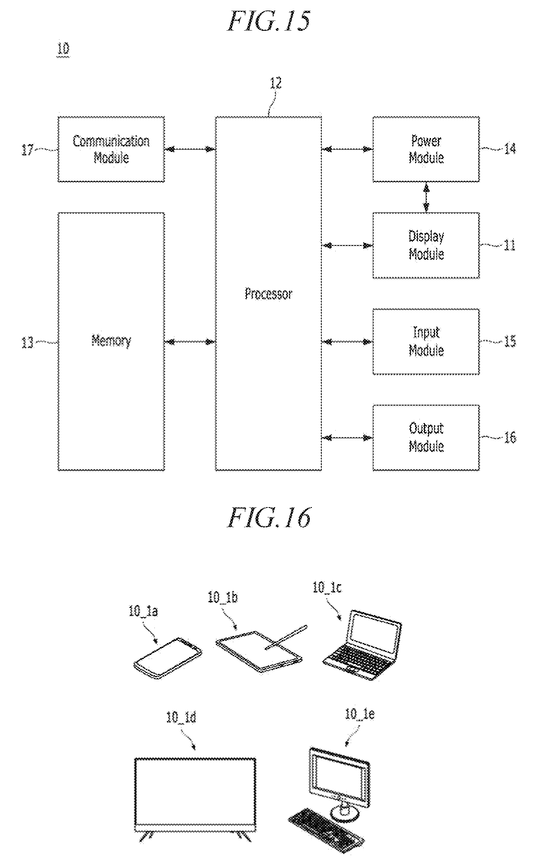

FIGS. 16 through 18 are schematic views of electronic devices according to various embodiments of the present disclosure. FIGS. 16 through 18 illustrate examples of various electronic devices to which the display device according to the embodiments may be incorporated.

Illustrated in FIG. 16 as examples of electronic devices are a smartphone 10_1a, a tablet PC 10_1b, a laptop computer 10_1c, a TV 10_1d, and a desktop monitor 10_1e.

The smartphone 10_1a may include, in addition to a display module, an input module such as a touch sensor and a communication module. The smartphone 10_1a may be configured to process information received through the communication module or another input module, and display the information via the display module of the display device.

The tablet PC 10_1b, laptop computer 10_1c, TV 10_1d, and desktop monitor 10_1e may similarly include a display module and an input module and may additionally include a communication module, depending on the implementation.

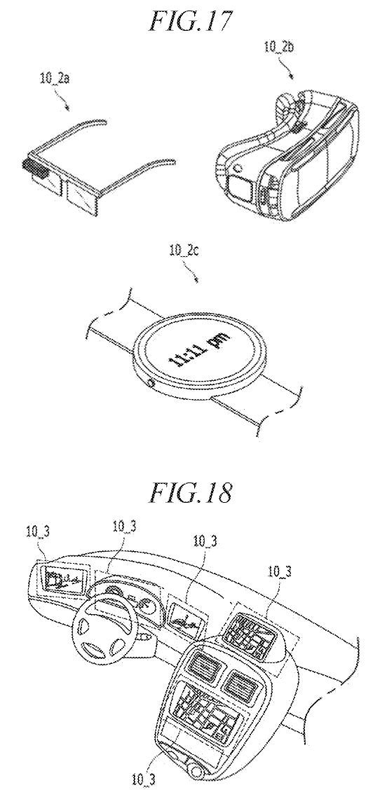

FIG. 17 illustrates an example in which an electronic device including a display module is incorporated in a wearable electronic device. The wearable electronic device may be a pair of smart glasses 10_2a, a head-mounted display 10_2b, or a smartwatch 10_2c.

The smart glasses 10_2a and the head-mounted display 10_2b may include a display module that is configured to emit display images and a reflector that is configured to reflect the emitted display screen to the user’s eyes, thereby providing virtual reality or augmented reality screens to the user.

The smartwatch 10_2c may include a biometric sensor as an input device and may be configured to provide biometric information, detected through the biometric sensor, to the user via the display module.

FIG. 18 illustrates an example in which an electronic device including a display module is incorporated in a vehicle. For example, the electronic device 10_3 may be applied to a dashboard or center fascia of an automobile or may be applied to a Center Information Display (CID) disposed on the dashboard or a room mirror display replacing a side mirror.

While certain non-limiting example embodiments of the present disclosure have been described above with reference to the accompanying drawings, persons of ordinarily skill in the art to which the present disclosure pertains shall appreciate that there may be a variety of modifications and permutations of embodiments of the present disclosure without departing from the spirit and scope of the present disclosure. Moreover, it shall be appreciated that the described embodiments are not intended to restrict the present disclosure thereto and that the modifications and permutations of the embodiments of the present disclosure, and equivalents of aspects of embodiments of the present disclosure, are included within the spirt and scope of the present disclosure.

What is claimed is:

1. A display device comprising:
a substrate;
a circuit layer on the substrate;
first electrodes on and connected to the circuit layer;
a bank between the first electrodes;
a first functional layer on the first electrodes and at least partially in contact with the bank;
a pixel defining film on the first functional layer, wherein the pixel defining film defines light-emitting regions, and the first electrodes are at least partially in the light-emitting regions;
a light-emitting layer on the first functional layer;
a second functional layer on the light-emitting layer; and
a second electrode on the second functional layer,
wherein the first functional layer has a first thickness in a first light-emitting region among the light-emitting regions and has a second thickness different from the first thickness in a second light-emitting region among the light-emitting regions.

2. The display device of claim 1, wherein at least one of the first electrodes and the bank are spaced apart from each other, and a groove is defined by and between the pixel defining film and the bank, and
wherein a portion of the first functional layer is in the groove.

3. The display device of claim 1, wherein the first functional layer is in contact with the circuit layer.

4. The display device of claim 1, wherein the first functional layer is on an entire upper surface of at least one of the first electrodes.

5. The display device of claim 1, wherein a non-light-emitting region is defined between the light-emitting regions, and
wherein, in a direction from the light-emitting regions toward the non-light-emitting region, the first functional layer is between the pixel defining film and the bank.

6. The display device of claim 1, wherein the first functional layer is in contact with the circuit layer, the first electrodes, the bank, the pixel defining film, and the light-emitting layer.

7. The display device of claim 1, wherein the first functional layer comprises at least one from among a hole injection layer and a hole transport layer.

8. The display device of claim 1, further comprising:
a light-emitting stack between the second electrode and the second functional layer; and
a charge generation layer between the second functional layer and the light-emitting stack,
wherein the light-emitting stack comprises:
at least one stack hole functional layer;
at least one stack light-emitting layer; and
at least one stack electron functional layer.

9. The display device of claim 1, wherein a first distance between a top surface of the bank and the substrate is greater than a second distance between a top surface of the pixel defining film and the substrate.

10. The display device of claim 1, wherein the bank is on at least one of the first electrodes.

11. The display device of claim 1, wherein the pixel defining film extends over an upper portion of the bank.

12. The display device of claim 11, wherein a non-light-emitting region is between the light-emitting regions, and
wherein the pixel defining film is on a portion of the first functional layer, the portion of the first functional layer overlapping with the non-light-emitting region in a plan view.

13. The display device of claim 1, wherein a non-light-emitting region is between the light-emitting regions, and
wherein a portion of the first functional layer overlapping with the non-light-emitting region in a plan view is exposed between the pixel defining film and the bank.

14. The display device of claim 1, further comprising:
an encapsulation layer on the second electrode; and
a color conversion layer on the encapsulation layer.

15. The display device of claim 1, further comprising:
an encapsulation layer on the second electrode; and
a color filter layer on the encapsulation layer.

16. The display device of claim 1, wherein the bank comprises a lyophobic material.

17. The display device of claim 1, wherein the bank comprises a colored light-shielding material, and
wherein the pixel defining film comprises a transparent or translucent insulating film.

18. A method for manufacturing a display device, the method comprising:
providing a circuit layer on a substrate;
providing first electrodes on the circuit layer;
providing a bank between the first electrodes;
providing a first functional layer on the first electrodes and at least partially in contact with the bank;
providing a pixel defining film on the first functional layer;
providing a light-emitting layer on the first functional layer;
providing a second functional layer on the light-emitting layer; and
providing a second electrode on the second functional layer,
wherein the pixel defining film defines light-emitting regions, and the first electrodes are at least partially in the light-emitting regions, and
wherein the first functional layer has a first thickness in a first light-emitting region among the light-emitting regions and has a second thickness different from the first thickness in a second light-emitting region among the light-emitting regions.

19. An electronic device comprising:
a display device comprising:
a substrate;
a circuit layer on the substrate;
first electrodes on and connected to the circuit layer;
a bank between the first electrodes;
a first functional layer on the first electrodes and at least partially in contact with the bank;
a pixel defining film on the first functional layer, wherein the pixel defining film defines light-emitting regions, and the first electrodes are at least partially in the light-emitting regions;
a light-emitting layer on the first functional layer;
a second functional layer on the light-emitting layer; and
a second electrode on the second functional layer,
wherein the first functional layer has a first thickness in a first light-emitting region among the light-emitting regions and has a second thickness different from the first thickness in a second light-emitting region among the light-emitting regions.

20. The electronic device of claim 19, further comprising:
a processor configured to control the display device;
a memory storing data for operation of the display device or the processor; and
a power converter configured to generate or supply power.
